(19) United States
(12) Patent Application Publication
(10) Pub. No.: US 2024/0379329 A1
(43) Pub. Date: Nov. 14, 2024

(54) HIGH EFFICIENCY MICROWAVE PLASMA APPLICATOR

(71) Applicant: Applied Materials, Inc,, Santa Clara, CA (US)

(72) Inventors: Thai Cheng Chua, Cupertino, CA (US); ADAM FISCHBACH, Campbell, CA (US); CHRISTIAN VALENCIA, Alhambra, CA (US); RICHARD MCKISSICK, San Jose, CA (US); BRIAN HATCHER, San Jose, CA (US)

(21) Appl. No.: 18/144,747

(22) Filed: May 8, 2023

(51) Int. Cl. H01J 37/32

(52) U.S. Cl. CPC H01J 37/32211; H01J 37/32348; H01J 37/32357

(57) ABSTRACT

Embodiments disclosed herein include a remote plasma source. In an embodiment, the remote plasma source comprises a housing where a fluidic channel passes from a first end to a second end of the housing. In an embodiment, an applicator intersects the fluidic channel. In an embodiment, the applicator comprises a dielectric body, and a pin inserted in a hole in the dielectric body.

### BACKGROUND

### 1) Field

Embodiments relate to the field of semiconductor manufacturing and, in particular, to high efficiency microwave plasma applicators.

### 2) Description of Related Art

In semiconductor manufacturing, some processes require the use of a remote plasma source. A remote plasma source includes an antechamber that is fluidically coupled to the main processing chamber. The plasma is struck in the antechamber and excited gas molecules flow out an exhaust that couples the antechamber to the main processing chamber. In this way, the plasma is moved away from the surface of the substrate that is being processed in the main processing chamber.

In some applications, the remote plasma source comprises a resonating body, which can sometimes be referred to as a puck. A conductive pin is inserted into a hole in the axial center of the resonating body. The conductive pin is coupled to the power source. In some instances the power source may be a microwave power source.

### SUMMARY

Embodiments disclosed herein include a remote plasma source. In an embodiment, the remote plasma source comprises a housing where a fluidic channel passes from a first end to a second end of the housing. In an embodiment, an applicator intersects the fluidic channel. In an embodiment, the applicator comprises a dielectric body, and a pin inserted in a hole in the dielectric body.

Embodiments disclosed herein include a semiconductor processing tool. In an embodiment, the tool comprises a processing chamber, and a remote plasma source fluidically coupled to the processing chamber. In an embodiment, the remote plasma source comprises a housing with a first end and a second end, and a dielectric body at least partially within the housing between the first end and the second end. In an embodiment, a pin is in a hole in the dielectric body.

Embodiments disclosed herein include semiconductor processing tools. In an embodiment, the tool comprises a processing chamber, and a remote plasma source coupled to the processing chamber. In an embodiment, the remote plasma source comprises a housing with a fluidic path, where a gas inlet is provided at a first end of the fluidic path, and an exhaust is provided at a second end of the fluidic path. In an embodiment, the exhaust is coupled to the processing chamber. In an embodiment, a microwave applicator intersects the fluidic path, where the remote plasma source is configured to flow a gas through the fluidic path around the microwave applicator.

### BRIEF DESCRIPTION OF THE DRAWINGS

FIG. 1A is an illustration of the housing and an applicator of a remote plasma source, in accordance with an embodiment.

FIG. 1B is an illustration of the housing and an applicator of a remote plasma source with a dielectric liner, in accordance with an embodiment.

FIG. 2A is a perspective view illustration of a remote plasma source, in accordance with an embodiment.

FIG. 2B is a cross-sectional illustration of a remote plasma source with an applicator that intersects a fluidic path through the housing, in accordance with an embodiment.

FIG. 2C is a cross-sectional illustration of a remote plasma source with an applicator along a path between the first end and the second end of the housing, in accordance with an embodiment.

FIG. 3A is a cross-sectional illustration of a remote plasma source with an applicator that intersects a fluidic path through the housing, where an interior surface of the housing has a dielectric lining, in accordance with an embodiment.

FIG. 3B is a cross-sectional illustration of a remote plasma source with an applicator along a path between the first end and the second end of a housing with an internal dielectric liner, in accordance with an embodiment.

FIG. 4A is an illustration of a semiconductor processing tool with a remote plasma source that is configured for high efficiency plasma generation, in accordance with an embodiment.

FIG. 4B is an illustration of a semiconductor processing tool with a first remote plasma before the chamber and a second remote plasma along the foreline, in accordance with an embodiment.

FIG. 5 illustrates a block diagram of an exemplary computer system that may be used in conjunction with a processing tool, in accordance with an embodiment.

### DETAILED DESCRIPTION

Systems described herein include high efficiency microwave plasma applicators. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

In some remote plasma architectures, the applicator is provided adjacent to the fluidic path through the housing. For example, if gas flows from left to right, the applicator may be provided over a top surface of the fluidic path. As such, power (e.g., microwave power) is coupled to the gas through a single surface. This can lead to sub-optimal power transfer. That is, much of the power from the applicator is not coupled into the gas to form a plasma.

In some instances, the applicator has a cylindrical shape with a pin or monopole extending down an axial center of the applicator. In such a configuration, microwave power is emitted from the bottom surface of the applicator in addition to the sidewalls of the applicator. In a configuration such as the one described above, only the microwave power emitted from the bottom surface of the applicator is used to form plasma. Also, it is to be appreciated that the strength of the electromagnetic field decreases with distance away from the applicator.

Accordingly, embodiments disclosed herein include remote plasma architectures that have an improved architecture. The improved architecture uses more of the microwave power. For example, sidewalls of the applicator are also used to generate plasma. Further, the fluidic path is constricted around the applicator so that the higher electromagnetic field proximate to the applicator surfaces is used to generate the plasma. Such embodiments allow for high efficiency microwave plasma generation. For example, some embodiments disclosed herein enable pure hydrogen plasma at very low pressures (e.g., below 1 Torr, or even below 50 mTorr).

In an embodiment, the remote plasma architectures described herein include a housing. The housing has a first end and a second end opposite from the first end. A passage internal to the housing (e.g., a fluidic path) is provided from the first end to the second end. A gas inlet may be provided at the first end, and an exhaust may be provided at the second end. In an embodiment, an applicator is inserted through a wall of the housing so that the applicator intersects the fluidic path. The applicator constricts the flow of gasses flown from the first end to the second end. The gas flows through small gaps between the applicator and the internal surface of the housing. This exposes the gas to a high electromagnetic field which enhances plasma generation.

In some embodiments, the internal surfaces of the housing may also be coated with a liner. The liner may be a dielectric material, such as a ceramic or the like. The presence of the liner may reduce escaping electrons and further improve the generation of the plasma.

In an embodiment, a remote plasma source, such as those described herein, may be provided upstream of a main processing chamber. That is, excited gas from the plasma may flow through an exhaust of the remote plasma source and into the main processing chamber. As such, substrates within the main processing chamber are removed from the plasma environment, which may reduce damage to the substrate. In some embodiments, a downstream remote plasma source may also be used. For example, a remote plasma source, such as those described herein, may be provided along a foreline between the main processing chamber and the pump. Such an embodiment may be used in order to provide cleaning of the foreline.

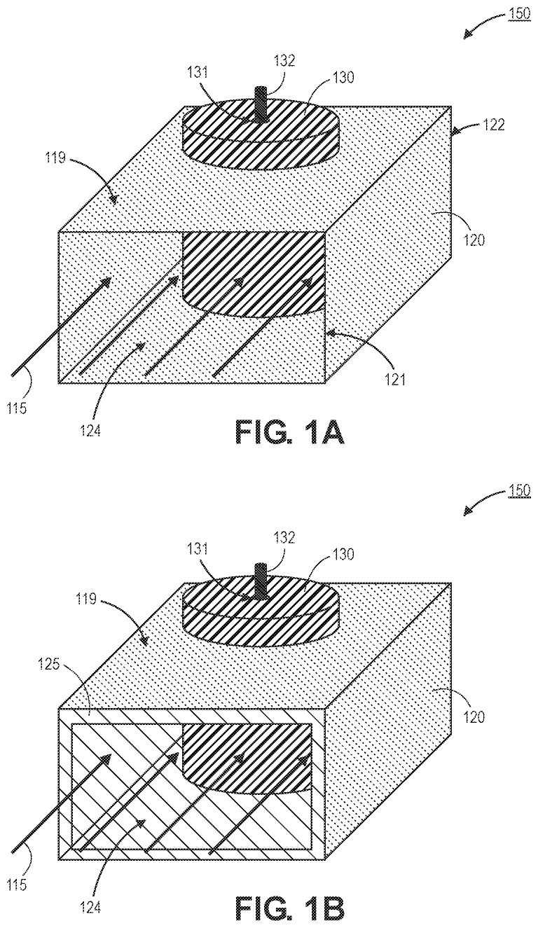

Referring now to FIG. 1A, a perspective view illustration of a remote plasma source 150 is shown, in accordance with an embodiment. In an embodiment, the remote plasma source 150 may comprise a housing 120. In the illustrated embodiment, only the internal surfaces of the housing 120 are shown for clarity. That is, the housing 120 may include a solid structure that surrounds the fluidic path 124. The housing 120 may be any suitable material. For example, the housing 120 may comprise aluminum. In an embodiment, the fluidic path 124 is a voided region of the housing between a first end 121 of the housing 120 and a second end 122 of the housing 120. The fluidic path 124 may have a roughly rectangular volume. Though other shapes of the fluidic path 124 are also possible in some embodiments.

In an embodiment, an applicator 130 may be inserted into the housing 120. For example, the applicator 130 may intersect the fluidic path 124. The applicator 130 may be at roughly a center point between the first end 121 and the second end 122. Though, the applicator 130 may be provided at any location between the first end 121 and the second end 122. In an particular embodiment, the applicator 130 may pass through a top surface 119 of the housing 120. That is, a portion of the applicator 130 may be outside of the fluidic path 124 and within the fluidic path 124.

In an embodiment, the applicator 130 may be any suitable shape for microwave power transfer. In the illustrated embodiment, the applicator 130 has a cylindrical shape. Though, other shapes may also be used. In an embodiment, a pin 132 may be inserted into a hole 131 of the applicator 130. The pin 132 and the hole 131 may be at an axial center of the applicator 130. The pin 132 may be coupled to a power source. For example, the power source may be a solid state microwave power source in some embodiments. The applicator 130 may be any material suitable for microwave power transfer. For example, the applicator 130 may comprise a dielectric material. In some embodiments, the applicator 130 may comprise alumina. In yet another embodiment, a coating (e.g., a dielectric coating) may be provided over surfaces of the applicator 130. A coating may provide improved protection against a plasma environment within the fluidic path 124.

In an embodiment, gas 115 flows from the first end 121 of the housing 120 to a second end 122 of the housing 120. Due to the presence of the applicator 130, the path of the gas 115 is constricted. That is, the gas will flow through confined gaps between the sidewall of the applicator 130 and the housing 120 and between the bottom of the applicator 130 and the housing. For example, the gaps may be approximately 10 mm or smaller. The gaps may confine the gas 115 to high electromagnetic field regions proximate to the applicator 130. Accordingly, improved plasma generation efficiency is provided.

Referring now to FIG. 1B, an illustration of a remote plasma source 150 is shown, in accordance with an additional embodiment. The remote plasma source 150 may comprise a housing 120. The housing 120 in FIG. 1B may be similar to the housing 120 in FIG. 1A. That is, gas 115 may flow through a fluidic path 124 within the housing 120. Additionally, an applicator 130 may be inserted into the fluidic path 124. The applicator 130 may be similar to the applicator 130 in FIG. 1A. For example, the applicator 130 may be inserted through a top surface 119 of the housing 120. The applicator 130 may have a pin 132 that is inserted into a hole 131 at the axial center of the applicator 130.

In an embodiment, the remote plasma source 150 may further comprise a liner 125. The liner 125 may cover the internal surface of the housing that defines the fluidic path 124. The liner 125 may be a dielectric material. As such, escaping electrons from the plasma are reduced, and efficiency of the plasma is improved. In an embodiment, the liner 125 may be a ceramic material. For example, the liner 125 may comprise alumina. In some embodiments, the liner 125 may be the same material as the applicator 130. Though, the liner 125 and the applicator 130 may be different materials. For example, the liner 125 may be a material that is resistant to the plasma environment within the fluidic path 124.

In an embodiment, the flow of the gas 115 may be constricted by the presence of applicator 130 within the fluidic path 124. For example, the gas 115 may flow in gaps between the sidewall of the applicator 130 and the liner 125, and between the bottom of the applicator 130 and the liner 125. In an embodiment, the gaps may be approximately 10 mm or smaller. The gaps may confine the gas 115 to high electromagnetic field regions proximate to the applicator 130. Accordingly, improved plasma generation efficiency is provided.

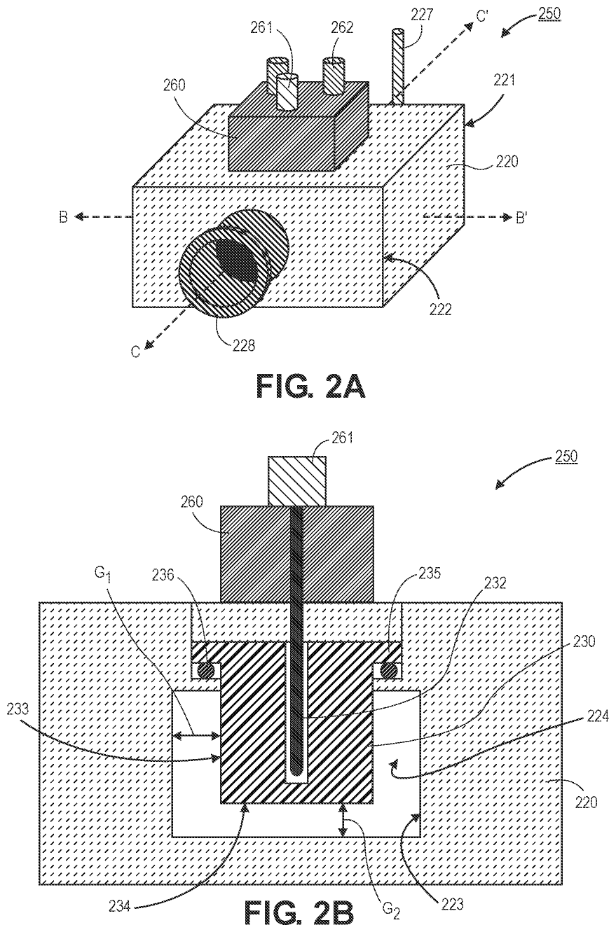

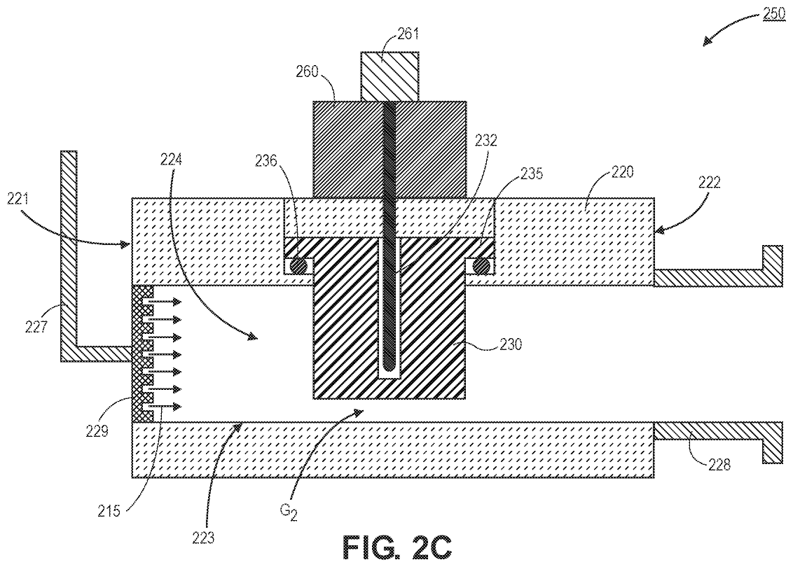

Referring now to FIG. 2A, a perspective view illustration of remote plasma source 250 is shown, in accordance with an embodiment. As shown, the remote plasma source 250 may comprise a housing 220. The housing 220 may have a first end 221 and a second end 222 opposite from the first end 221. The first end 221 may be coupled to a gas inlet 227. The second end 222 may be coupled to an exhaust 228. The fluidic path (not visible in FIG. 2A) may pass from the first end 221 to the second end 222. For example, the fluidic path may start at the gas inlet 227 and end at the exhaust 228. In an embodiment, the housing 220 may comprise any suitable material. For example, the housing 220 may comprise aluminum or the like.

In an embodiment, a matching unit 260 may be coupled to the housing 220. The matching unit 260 may be any suitable match architecture. The match architecture may allow for impedance tuning between a power source (not shown) and the plasma load within the remote plasma source. The matching unit 260 may be electrically coupled to the applicator (not visible in FIG. 2A). The matching unit 260 may comprise a connector or coupler 261 that couples the matching unit 260 to the power source (e.g., a solid state microwave power source). The matching unit 260 may also be an actively cooled component. For example, cooling fluid inlets/outlets 262 may be provided on the matching unit 260.

In an embodiment, the matching unit 260 is provided over the applicator. For example, the applicator may extend into the housing 220 in order to intersect the fluidic path 224. That is, an applicator similar to those described above in FIGS. 1A and 1B may be used. A more detailed description of the applicator is provided below with respect to the cross-sectional illustrations in FIGS. 2B and 2C.

Referring now to FIG. 2B, a cross-sectional illustration of the remote plasma source 250 in FIG. 2A along line B-B′ is shown, in accordance with an embodiment. The cross-section in FIG. 2B is through the applicator 230 and transverse to the direction of the fluidic path 224 (which is into and out of the plane of FIG. 2B). As shown, the housing 220 includes an interior surface 223. The interior surface 223 defines the fluidic path 224. As shown, the applicator 230 extends into the fluidic path 224. For example, the applicator 230 may include a wider top portion 235 that is compressed against an O-ring 236 or other type of gasket. The applicator 230 may have surfaces that are exposed to the volume of the fluidic path 224. For example, the applicator 230 may include sidewalls 233 and a bottom surface 234 that are exposed to the fluidic path 224.

In an embodiment, the applicator 230 confines the flow of gasses along the fluidic path 224. For example, the gasses may flow through first gaps G₁ and second gap G₂. The first gaps G₁ are between the sidewalls 233 and the interior surface 223 of the housing 220, and the second gap G₂ is between the bottom surface 234 and the interior surface 223 of the housing 220. In an embodiment, the dimensions of the first gap G₁ and the second gap G₂ are substantially equal to each other. In other embodiments, the first gap G₁ has a different dimension than the second gap G₂. The gaps G₁ and G₂ are small enough to confine the gas flow to high electromagnetic field regions generated by the applicator 230. For example, the gaps G₁ and G₂ may be approximately 10 mm or smaller, or approximately 1 mm or smaller. Due to the high electromagnetic field in the gaps G₁ and G₂ plasma is efficiently formed in the gaps G₁ and G₂. That is, (as viewed in the cross-section of FIG. 2B) the plasma of the remote plasma source 250 may be formed in a U-shape around the applicator 230.

In an embodiment, the applicator 230 may be a dielectric material. For example, the applicator 230 may comprise alumina in some embodiments. The applicator 230 includes a hole into which a pin 232 is inserted. The hole and the pin 232 may be provided in an axial center of the applicator 230. More generally, the major direction of the pin 232 (i.e., up and down in FIG. 2B) may be substantially orthogonal to a direction of the fluidic path 224 (i.e., into and out of the page of FIG. 2B).

In an embodiment, a matching unit 260 may be coupled to the pin 232. The matching unit 260 may be similar to the matching unit 160 described in greater detail above. The matching unit 260 may comprise a connector or coupler 261. The coupler 261 may be configured to receive a cable that transmits power from a power source (e.g., a solid state microwave power source).

Referring now to FIG. 2C, a cross-sectional illustration of the remote plasma source 250 in FIG. 2A along line C-C′ is shown, in accordance with an embodiment. The plane of FIG. 2C is provided along a length of the fluidic path 224. For example, a first end 221 and a second end 222 of the housing 220 are visible in FIG. 2C. As shown, the applicator 230 is inserted into the fluidic path 224 between the first end 221 and the second end 222. For example, the applicator 230 is shown as being at an approximate midpoint of the fluidic path 224. Though, the applicator 230 may be at any position along the fluidic path 223. As shown in FIG. 2C, the fluidic path 224 is confined at the location of the applicator 230. For example, one confined portion of the fluidic path 224 is located at the second gap G₂ between the internal surface 223 of the housing 220 and the bottom of the applicator 230.

In an embodiment, the first end 221 of the housing 220 may be coupled to a gas input 227. The gas input 227 may include functionality to feed one or more different gasses into the fluidic path 224. In some embodiments, the gas may be distributed throughout the fluidic path 224 by a showerhead 229 or other gas distribution feature. The showerhead 229 may be fluidically coupled to the gas input 227. Alternatively, the gas input 227 may be directly coupled to the fluidic path 224 without an intervening gas distribution feature.

In an embodiment, the second end 222 of the housing 228 may comprise an exhaust 228. The exhaust 228 may comprise a flange for coupling to a main processing chamber (not shown) or to any other location in a semiconductor processing tool.

As shown, the gas 215 may flow from the gas distribution feature 229 towards the applicator 230. Due to the high electromagnetic field proximate to the applicator 230, a plasma may be struck around the applicator. The plasma may be formed along the sidewalls and the bottom surface of the applicator 230. Excited gasses may then continue along the fluidic path 224 towards the exhaust 228 at the second end 222 of the housing 220.

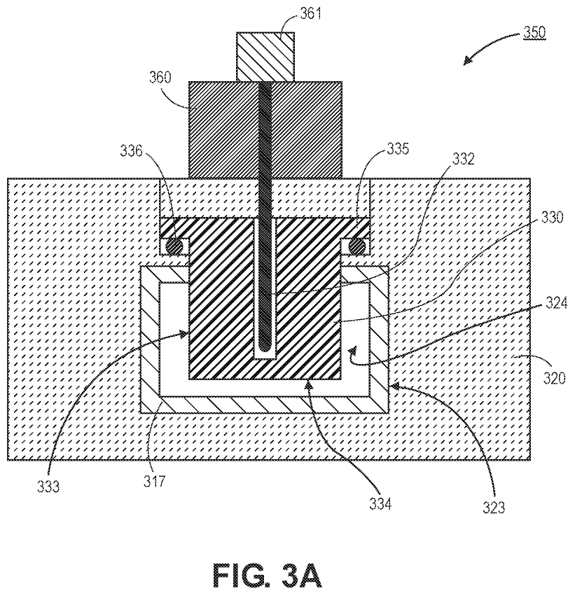

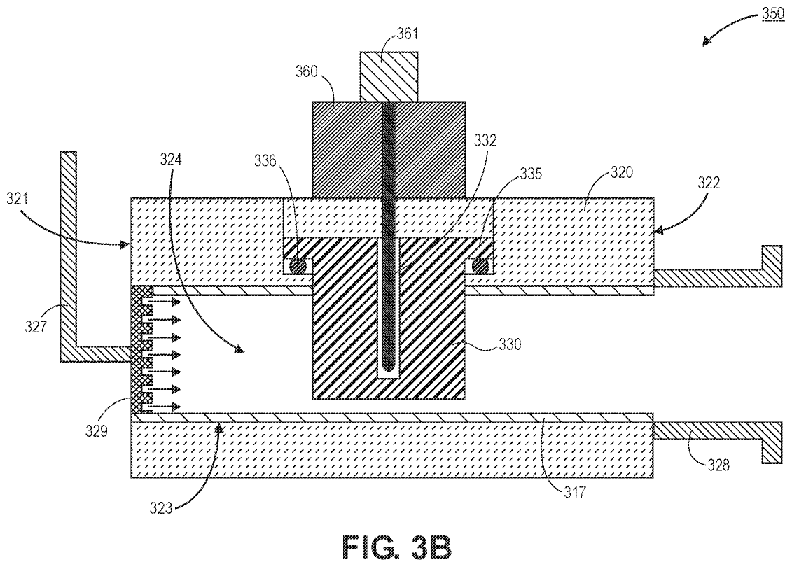

Referring now to FIG. 3A, a cross-sectional illustration of the remote plasma source 350 through the applicator 330 and transverse to the direction of the fluidic path 324 (which is into and out of the plane of FIG. 3A) is shown, in accordance with an embodiment. As shown, the housing 320 includes an interior surface 323. In an embodiment, a liner 317 may be provided along the interior surface 323. The liner 317 may be a dielectric material. For example, the liner 317 may comprise alumina or the like. The liner 317 may be a material that is resistant to the plasma environment within the remote plasma source 350. The liner 317 may be approximately 10 cm thick or thinner. Though, thicker liners 317 may also be used in some embodiments.

In an embodiment, the interior surface of the liner 317 may define the fluidic path 324. As shown, the applicator 330 extends into the fluidic path 324. For example, the applicator 330 may include a wider top portion 335 that is compressed against an O-ring 336 or other type of gasket. The applicator 330 may have surfaces that are exposed to the volume of the fluidic path 324. For example, the applicator 330 may include sidewalls 333 and a bottom surface 334 that are exposed to the fluidic path 324.

In an embodiment, the applicator 330 confines the flow of gasses along the fluidic path 324. For example, the gasses may flow through gaps between the sidewalls 333 and the liner 317 and the between the bottom surface 334 and the liner 317. The gaps are small enough to confine the gas flow to high electromagnetic field regions generated by the applicator 330. For example, the gaps may be approximately 10 mm or smaller, or approximately 1 mm or smaller. Due to the high electromagnetic field in the gaps, plasma is efficiently formed in the gaps. That is, (as viewed in the cross-section of FIG. 3A) the plasma of the remote plasma source 350 may be formed in a U-shape around the applicator 330.

In an embodiment, the applicator 330 may be a dielectric material. For example, the applicator 330 may comprise alumina in some embodiments. The applicator 330 includes a hole into which a pin 332 is inserted. The hole and the pin 332 may be provided in an axial center of the applicator 330. More generally, the major direction of the pin 332 (i.e., up and down in FIG. 3A) may be substantially orthogonal to a direction of the fluidic path 324 (i.e., into and out of the page of FIG. 3A).

In an embodiment, a matching unit 360 may be coupled to the pin 332. The matching unit 360 may be similar to the matching unit 160 described in greater detail above. The matching unit 360 may comprise a connector or coupler 361. The coupler 361 may be configured to receive a cable that transmits power from a power source (e.g., a solid state microwave power source).

Referring now to FIG. 3B, a cross-sectional illustration of the remote plasma source 350 along a length of the fluidic path 324 is shown, in accordance with an embodiment. For example, a first end 321 and a second end 322 of the housing 320 are visible in FIG. 3B. As shown, the applicator 330 is inserted into the fluidic path 324 between the first end 321 and the second end 322. For example, the applicator 330 is shown as being at an approximate midpoint of the fluidic path 324. Though, the applicator 330 may be at any position along the fluidic path 323. As shown in FIG. 3B, the fluidic path 324 is confined at the location of the applicator 330. For example, one confined portion of the fluidic path 324 is located at the gap between the liner 317 and the bottom of the applicator 330.

In an embodiment, the first end 321 of the housing 320 may be coupled to a gas input 327. The gas input 327 may include functionality to feed one or more different gasses into the fluidic path 324. In some embodiments, the gas may be distributed throughout the fluidic path 324 by a showerhead 329 or other gas distribution feature. The showerhead 329 may be fluidically coupled to the gas input 327. Alternatively, the gas input 327 may be directly coupled to the fluidic path 324 without an intervening gas distribution feature.

In an embodiment, the second end 322 of the housing 328 may comprise an exhaust 328. The exhaust 328 may comprise a flange for coupling to a main processing chamber (not shown) or to any other location in a semiconductor processing tool.

As shown, the gas 315 may flow from the gas distribution feature 329 towards the applicator 330. Due to the high electromagnetic field proximate to the applicator 330, a plasma may be struck around the applicator. The plasma may be formed along the sidewalls and the bottom surface of the applicator 330. Excited gasses may then continue along the fluidic path 324 towards the exhaust 328 at the second end 322 of the housing 320.

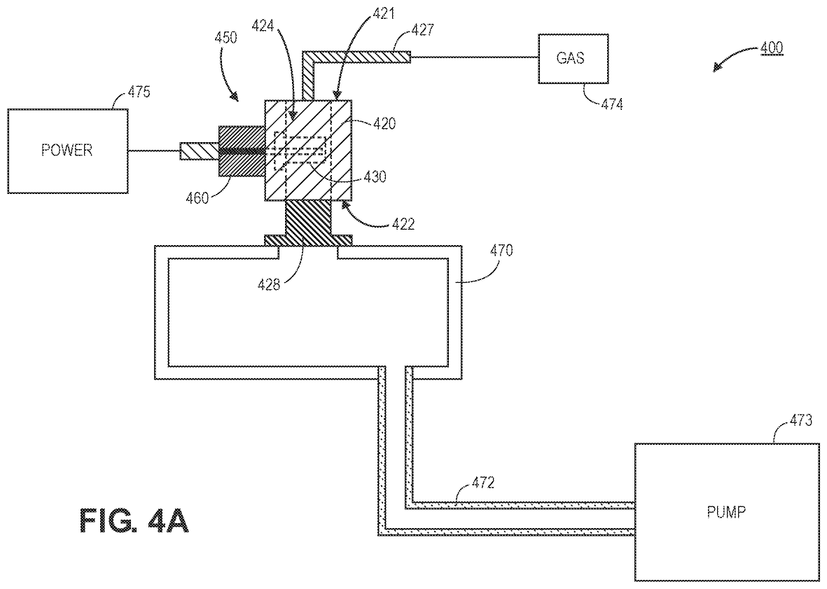

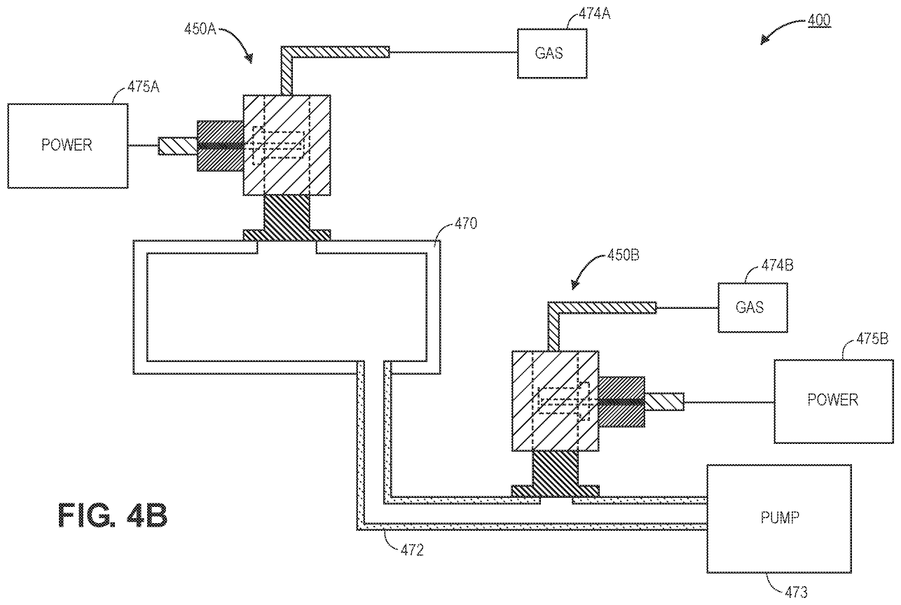

Referring now to FIG. 4A, an illustration of a semiconductor processing tool 400 is shown, in accordance with an embodiment. The processing tool 400 may include a main processing chamber 470. The main processing chamber 470 may be a sub-atmospheric chamber, such as a vacuum chamber. One or more substrates (e.g., wafers) may be provided in the main processing chamber 470 for processing. The processing may include any plasma assisted process. For example, the processing may be an etching process, a deposition process, a plasma treatment process, or the like.

In an embodiment, a remote plasma source 450 is provided on the upstream side of the main processing chamber 470. As shown, the remote plasma source 450 comprises a housing 420. The housing 420 may include an internal fluidic path 424. An applicator 430 may intersect the fluidic path 424. A first end 421 of the housing 420 may be coupled to a gas inlet 427. The gas inlet 427 may be coupled to one or more gas sources 474. In an embodiment, a second end 422 of the housing 420 may include an exhaust 428 that is fluidically coupled to the main processing chamber 470.

In an embodiment, the applicator 430 may be coupled to a matching system 460. The matching system 460 may be coupled to a power source 475. For example, the power source 475 may be a microwave power source 475. More particularly, the power source 475 may be a solid state microwave power source 475.

In an embodiment, the remote plasma source 450 may be similar to any of the remote plasma sources described in greater detail above. For example, the remote plasma source 450 may further comprise a liner, such as a dielectric ceramic liner over the interior surfaces of the housing 420 that define the fluidic path 424.

In an embodiment, the semiconductor processing tool 400 may further comprise a pump 473 that is provided along a foreline 472 downstream of the main processing chamber 470. The pump 473 may be used in order to generate the low pressure environment within the main processing chamber 470 and the remote plasma source 450.

Referring now to FIG. 4B, an illustration of a semiconductor processing tool 400 is shown in accordance with an additional embodiment. In the embodiment shown in FIG. 4B, a first remote plasma source 450A is provided on an upstream side of the main processing chamber 470, and a second remote plasma source 450B is provided on a downstream side of the main processing chamber 470. The first remote plasma source 450A may be coupled to a first power source 475A and a first gas source 474A. The second remote plasma source 450B may be coupled to a second power source 475B and a second gas source 474B.

The second remote plasma source 450B may be coupled to the foreline 472. In an embodiment, the second remote plasma source 450B may be used to clean the foreline 472. As such, the plasma chemistry within the second remote plasma source 450B may be different than the plasma chemistry within the first remote plasma source 450A.

In an embodiment, the first remote plasma source 450A and the second remote plasma source 450B may be similar to any of the remote plasma sources described in greater detail herein. For example, the housing may include a fluidic channel with an applicator intersecting the fluidic channel. In some embodiments, the fluidic channel may be lined with a dielectric liner, such as a ceramic liner.

As noted above, embodiments disclosed herein allow for highly efficient generation of plasma due to the processing gasses being confined to a narrow region around the applicator. These gaps experience very high electromagnetic fields in order to generate the plasma. Such embodiments are particularly useful for forming certain types of plasmas. For example, a pure hydrogen plasma may be provided in some embodiments. More particularly, the hydrogen plasma may be generated at low pressures, such as approximately 1 Torr or below, or approximately 50 mTorr or below. Such pure hydrogen plasmas are not compatible with conventional plasma generation techniques. Such pure H₂ plasmas at low pressures enable the transport of highly energetic H* species to the wafer surface, and allows for improved processing conditions.

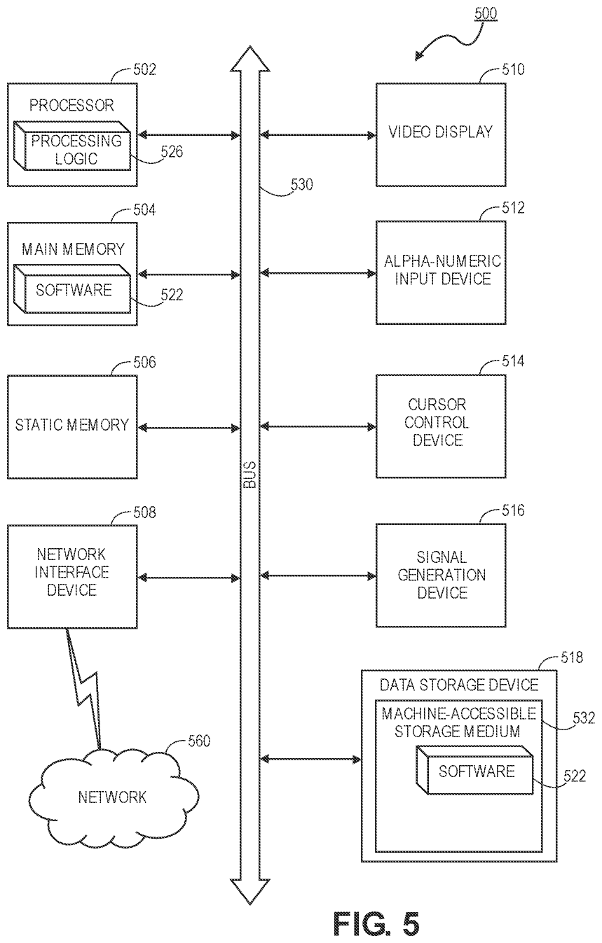

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 532 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 560 via the system network interface device 508. In an embodiment, the network interface device 508 may operate using RF coupling, optical coupling, acoustic coupling, or inductive coupling.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A remote plasma source, comprising:
a housing, wherein a fluidic channel passes from a first end to a second end of the housing; and
an applicator intersecting the fluidic channel, wherein the applicator comprises:
a dielectric body; and
a pin inserted in a hole in the dielectric body.

2. The remote plasma source of claim 1, wherein sidewalls of the dielectric body are spaced away from sidewalls of the fluidic channel by a gap.

3. The remote plasma source of claim 2, wherein the gap is approximately 10 mm or less.

4. The remote plasma source of claim 1, wherein a bottom of the dielectric body is spaced away from a bottom of the fluidic channel by a gap.

5. The remote plasma source of claim 4, wherein the gap is approximately 10 mm or less.

6. The remote plasma source of claim 1, wherein the dielectric body is cylindrical.

7. The remote plasma source of claim 1, wherein a dielectric liner is provided along interior surfaces of the fluidic channel.

8. The remote plasma source of claim 7, wherein the dielectric liner comprises a ceramic.

9. The remote plasma source of claim 1, wherein the housing comprises aluminum.

10. The remote plasma source of claim 1, further comprising:
a gas inlet at the first end of the housing; and
an exhaust at the second end of the housing.

11. The remote plasma source of claim 10, wherein the exhaust is fluidically coupled to a processing chamber.

12. A semiconductor processing tool, comprising:
a processing chamber; and
a remote plasma source fluidically coupled to the processing chamber, wherein the remote plasma source comprises:
a housing with a first end and a second end;
a dielectric body at least partially within the housing between the first end and the second end; and
a pin in a hole in the dielectric body.

13. The semiconductor processing tool of claim 12, further comprising:
a lining on an interior surface of the housing.

14. The semiconductor processing tool of claim 13, wherein the lining comprises a dielectric ceramic material.

15. The semiconductor processing tool of claim 12, wherein sidewall surfaces of the dielectric body and a bottom surface of the dielectric body are spaced away from internal surfaces of the housing by a gap.

16. The semiconductor processing tool of claim 15, wherein the gap is approximately 10 mm or less.

17. The semiconductor processing tool of claim 12, wherein the housing comprises aluminum.

18. A semiconductor processing tool, comprising:
a processing chamber; and
a remote plasma source coupled to the processing chamber, wherein the remote plasma source comprises:
a housing with a fluidic path, wherein a gas inlet is provided at a first end of the fluidic path, and an exhaust is provided at a second end of the fluidic path, wherein the exhaust is coupled to the processing chamber; and
a microwave applicator intersecting the fluidic path, wherein the remote plasma source is configured to flow a gas through the fluidic path around the microwave applicator.

19. The semiconductor processing tool of claim 18, wherein the microwave applicator comprises a cylinder with a pin inserted in an axial center of the cylinder, wherein the cylinder is a dielectric.

20. The semiconductor processing tool of claim 19, wherein the cylinder is spaced away from an interior surface of the housing by a gap that is approximately 10 mm or less.
